(19) United States
(12) Patent Application Publication
(10) Pub. No.: US 2002/0016043 A1
(43) Pub. Date: Feb. 7, 2002

(54) Semiconductor device

(75) Inventors: Rinya Hosono, Tsurugashima-Shi (JP); Shigeki Takayama, Sakado-Shi (JP)

Correspondence Address: FRISHAUF, HOLTZ, GOODMAN &, LANGER & CHICK, PC, 767 THIRD AVENUE, 25TH FLOOR, NEW YORK, NY, 10017-2023, US

(73) Assignee: TOKO, INC., Tokyo (JP)

(21) Appl. No.: 09/910,308

(22) Filed: Jul. 20, 2001

(30) Foreign Application Priority Data
Jul. 28, 2000 (JP) 2000-228883

(51) Int. Cl. H01L 21/336

(52) U.S. Cl. 438/297

(57) ABSTRACT

A semiconductor device having a current mirror circuit composed of a first transistor element Q11 and a second transistor element Q12 is used as a single transistor TD. A plurality of transistor elements for composing the first transistor element Q11 on the current referring side and a plurality of transistor elements for composing the second transistor element Q12 on the current reference side are dispersedly disposed to provide a uniform distribution density on a semiconductor substrate possibly.

### FIELD OF THE INVENTION

The present invention relates to a technique for improving characteristics of a semiconductor device used as a power transistor.

### DESCRIPTION OF THE PRIOR ART

FIG. 1 shows a circuit diagram of a typical series regulator. In the circuit of FIG. 1, an input terminal 1 is connected to an emitter of a PNP control transistor Q1, and a collector of the control transistor Q1 is connected to an output terminal 2. A base of the control transistor Q1 is connected to a collector of a NPN drive transistor Q2, and an emitter of the drive transistor Q2 is connected to the ground through a resistance R1. A base of the drive transistor Q2 is connected to an output terminal of an error amplifier circuit 3. One of input terminals of the error amplifier circuit 3 is connected to the ground through a reference voltage source 4. A series circuit of resistances R2 and R3 is provided between the output terminal 2 and the ground, and the other input terminal of the error amplifier circuit 3 is connected between the connecting point of the resistances R2 and R3. A phase correction capacitor CS may be optionally provided between the output terminal 2 and the ground to stabilize the operation of the regulator. The operation of such a regulator circuit is well known and its description will be omitted.

For achieving the regulator circuit shown in FIG. 1 in the form of an integrated circuit, a lateral type PNP transistor is often employed as the control transistor Q1. This is done because, in manufacturing a bipolar integrated circuit, NPN transistors and PNP transistors are more conveniently made into a vertical type and a lateral type, respectively.

The lateral type transistor characteristically has a current amplification factor (β or h_{FE}) which greatly varies depending on the value of the collector current (Ic) thereof. The relationship between the collector current and the current amplification factor of the lateral type transistors is generally represented by a characteristic curve as shown in FIG. 2, where a logarithmic scale is used for the horizontal axis. As seen in FIG. 2, the current amplification factor is maximized at a given value of the collector current, and decreases if the collector current becomes higher or lower than the given value.

When the control transistor Q1 in the circuit of FIG. 1 is composed of a lateral type transistor, its current amplification factor β_{Q1} varies along the characteristic curve shown in FIG. 2.

Depending on a load to be connected to the output terminal 2, the output current from the circuit of FIG. 1 varies. This output current corresponds to the collector current of the control transistor Q1. For example, it can be seen from FIG. 2 that the current amplification factor β_{Q1} of the control transistor Q1 decreases as the collector current increases as a result of increasing the load. Excessively lowered current amplification factor β_{Q1} of the control transistor Q1 can give rise to failure of the regulator in stabilizing the output. Thus, the circuitry of the error amplifier 3 and the drive transistor Q2 is typically arranged to have an increased feedback gain to allow the regulator to stabilize the output even if the current amplification factor β_{Q1} of the control transistor Q1 is low.

Conversely, when the collector current decreases as a result of reducing the load, the current amplification factor β_{Q1} of the control transistor Q1 increases. Whereat, the high current amplification factor β_{Q1} and high feedback gain obtained from the circuitry of the control transistor Q1, the error amplifier 3 and the drive transistor Q2 can cause unstable operations (e.g. oscillation) of the regulator.

Thus, the current amplification factor β_{Q1} is desirably arranged to have a small variation to the wide range of collector current and to be held in as high value as possible. Specifically, the characteristic curve shown in FIG. 2 is desirably arranged to have a flat shape and a high value.

A current amplification factor of a transistor is determined by various factors, such as each dimension, configuration, impurity density and formative depth of the collector and the emitter regions in the transistor. However, in practically manufacturing a semiconductor integrated circuit, the impurity density and formative depth of each region are often determined by manufacturing processes and other factors (e.g. reverse withstand voltage or leakage current). Thus, the characteristics of the semiconductor device are typically adjusted by modifying each dimension and the configuration of the collector and emitter regions to provide a desired level.

A transistor element for composing a lateral type PNP transistor can be obtained by forming P-type and N-type regions on a semiconductor substrate to make a pattern as schematically shown in FIG. 3. The transistor element shown in FIG. 3 comprises: a N-type region 11 formed at a given position on a semiconductor substrate; a first P-type region 12 formed on the N-type region 11 in a circular shape; and a second P-type region 13 provided with a window taking the form of a circle about the first P-type region 12 and formed to cover over the N-type region 11 excepting the window portion. The N-type region 11, first P-region 12 and second P-region 13 serve as a base region, emitter region and collector region, respectively. When the transistor is required to have a large current supply capacity, the plural number of the transistor element as in FIG. 3 are formed and used with connecting in parallel with each other.

In the transistor element having a pattern as shown in FIG. 3, its current amplification factor can be changed by adjusting the distance H between the outside diameter of the first P-type region 12 and the outside diameter of the window of the second P-type region 13. For example, the current amplification factor can be decreased by widening the distance H, and the current amplification factor can be conversely increased by narrowing the distance H.

However, when the distance H is modified, the value of the current amplification factor will be wholly increased or reduced in the form of multiplying the value by a certain fraction, as shown in FIG. 4. Thus, the peak value of the current amplification factor or the current amplification factor in the high domain of the collector current cannot be independently adjusted by means of modifying the distance H.

Consequently, it has been difficult to obtain a flat characteristic curve of the current amplification factor of the lateral type transistor while keeping the current amplification factor in a sufficiently high value. Additionally, in the series regulator shown in FIG. 1 using the lateral type transistor as the control transistor Q1, it has been required to provide a suitable device for preventing oscillation (e.g. phase correction capacitor) in the circuitry other than the control transistor Q1.

### SUMMARY OF THE INVENTION

It is therefore an object of the present invention to provide a lateral type power transistor or an allied semiconductor device capable of reducing variations in the current amplification factor to the wide range of collector current.

In order to achieve the above object, the present invention provides a semiconductor device comprising a given region formed on a semiconductor substrate, at least one first transistor element and at least one second transistor formed in the given region and composing a current mirror circuit, a first terminal provided in a line connected to a collector of the first transistor element, a second terminal provided in a line connected to each emitter of the first and second transistor elements, and a third terminal provided in a line connected commonly to each base of the first and second transistor elements. A part of the first and second transistor elements composing the current mirror circuit may be equivalently constructed by a multi-collector type transistor element.

In a first embodiment of the present invention, a plurality of transistor elements are formed in a given region on a semiconductor substrate, more specifically in an N-type semiconductor region serving as a common base region of the transistor elements. A part of the plurality of transistor elements are defined as second transistor elements, and the remainder are defined as first transistor elements. The first transistor elements are connected in parallel with each other. In the second transistor elements, each collector is electrically connected with each corresponding base and then the second transistor elements are connected in parallel with each other. Then, all emitters of the first and second transistor elements are electrically connected with each other and all bases of the first and second transistor elements are electrically connected with each other to make up a current mirror circuit.

Then, a collector terminal is provided in a line connected commonly to each collector of the first transistor elements, an emitter terminal being provided in a line connected commonly to each emitter of the first and second transistor elements, and a base terminal being provided in a line connected commonly to each base of the first and second transistor elements. Thus, one power transistor is constructed by all of the transistor elements. The plurality of first transistor elements and the plurality of second transistor elements are formed in the given region on the semiconductor substrate with dispersing them to provide a uniform distribution density possibly.

In a second embodiment of the present invention, a plurality of conventional first transistor elements and a plurality of multi-collector type second transistor elements each having first and second collectors are formed in a given region on a semiconductor substrate, more specifically in an N-type semiconductor region serving as a common base region of the transistor elements. The first transistor elements are connected in parallel with each other. In the multi-collector type of second transistor elements, each second collector is electrically connected with each corresponding base and then the second transistor elements are connected in parallel with each other.

Then, a collector terminal is provided in a line connected commonly to each collector of the first transistor elements and each first collector of the second transistor elements, an emitter terminal being provided in a line connected commonly to each emitter of the first and second transistor elements, and a base terminal being provided in a line connected commonly to each base of the first and second transistor elements. Thus, one power transistor is constructed by all of the transistor elements. The plurality of first transistor elements and the plurality of second transistor elements are formed in the given region on the semiconductor substrate with dispersing them to provide a uniform distribution density possibly.

### BRIEF DESCRIPTION OF THE DRAWINGS

FIG. 1 is a circuit diagram of a typical series regulator;

FIG. 2 is a characteristic curve diagram showing a relationship between a current amplification factor and collector current of a conventional typical lateral type transistor;

FIG. 3 shows a specific pattern of a conventional lateral type PNP transistor element;

FIG. 4 shows a characteristic variation measured when a distance H between each pattern of a conventional lateral type PNP transistor element is varied;

FIG. 5 is a circuit diagram showing a semiconductor device according to a first embodiment of the present invention and a series regulator including this semiconductor device;

FIG. 6 is a circuit diagram showing a basic construction of a semiconductor device of the present invention;

FIG. 7 is a characteristic curve diagram showing a relationship between a current amplification factor and collector current of a semiconductor device of the present invention;

FIG. 8 shows a first example of a pattern arrangement formed on a semiconductor substrate in a semiconductor device of the present invention;

FIG. 9 is an equivalent circuit diagram of a semiconductor device in the pattern arrangement as shown in FIG. 8;

FIG. 10 shows a second example of a pattern arrangement formed on a semiconductor substrate in a semiconductor device of the present invention;

FIG. 11 is an equivalent circuit diagram of a semiconductor device in the pattern arrangement as shown in FIG. 10;

FIG. 12 shows an equivalence relationship between a multi-collector type transistor element and a current mirror circuit;

FIG. 13 is a circuit diagram showing a semiconductor device according to a second embodiment of the present invention and a series regulator including this semiconductor device;

FIG. 14 shows a specific pattern of a lateral multi-collector type PNP transistor element;

FIG. 15 is a circuit diagram showing another basic construction of the semiconductor device according to the present invention;

FIG. 16 shows a third example of a pattern arrangement formed on a semiconductor substrate in a semiconductor device of the present invention;

FIG. 17 is an equivalent circuit diagram of a semiconductor device in the pattern arrangement as shown in FIG. 16;

FIG. 18 is an output characteristic diagram for explaining a stable operation range of a series regulator.

### DETAILED DESCRIPTION OF THE PREFERRED EMBODIMENTS

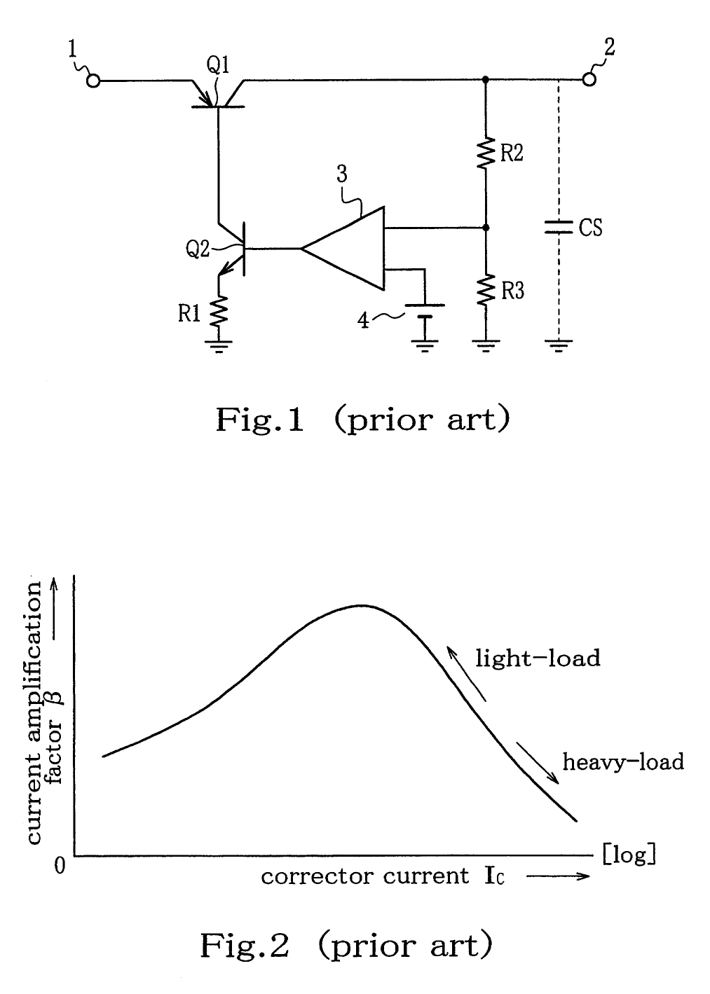

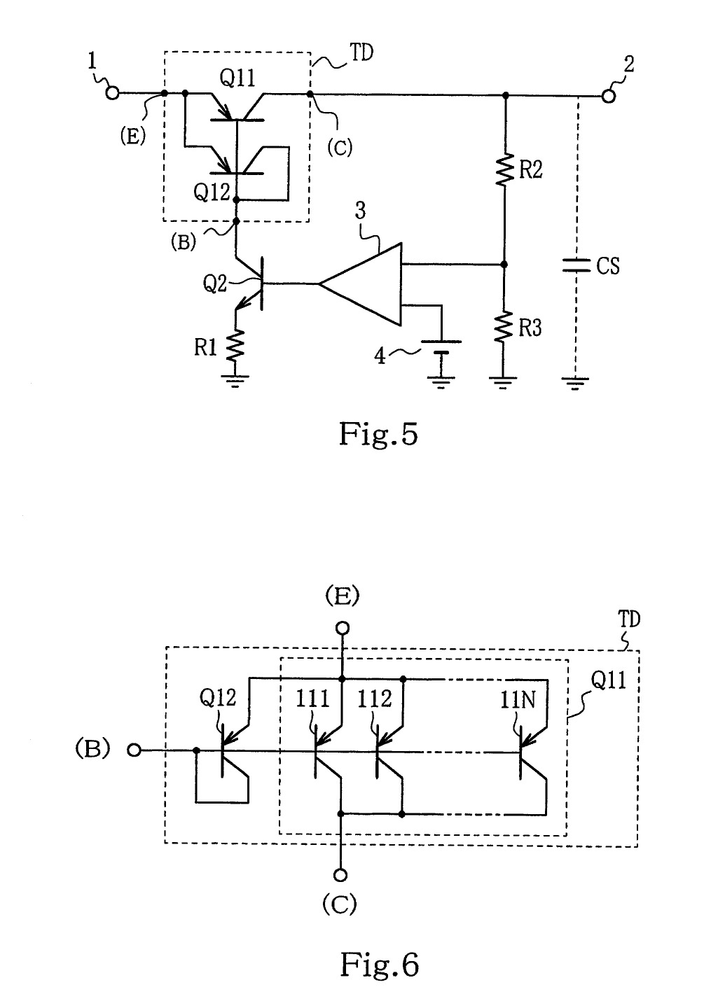

FIG. 1 shows a circuitry of a semiconductor device of the present invention capable of reducing variations of a current amplification factor to the wide range of collector current, and a series regulator using the semiconductor device. While a series regulator of FIG. 5 has a circuitry different from that of FIG. 1 in that a transistor TD is substituted for a control transistor Q1, other construction is the same as that of FIG. 1.

In the semiconductor device of the present invention, a first transistor element Q11 is combined with a second transistor element Q12 to use the combined transistor elements as a single transistor TD. This transistor TD has the following construction.

An emitter of the first transistor element Q11 and an emitter of the second transistor element Q12 are connected to each other. A base of the first transistor element Q11 and a base of the second transistor element Q12 are also connected to each other. The collector of the second transistor element Q12 is short-circuited to a base thereof. A collector terminal (C) is provided in a line connected to a collector of the first transistor element Q11. An emitter terminal (E) is provided in a line connected commonly to each emitter of the first and second transistor elements Q11 and Q12. A base terminal (B) is provided in a line connected commonly to each base of the first and second transistor elements Q11 and Q12. For achieving such a transistor TD, each of the first and second transistor elements Q11 and Q12 is constructed by a lateral type transistor having a common base region, and formed in a given N-type semiconductor region on a semiconductor substrate.

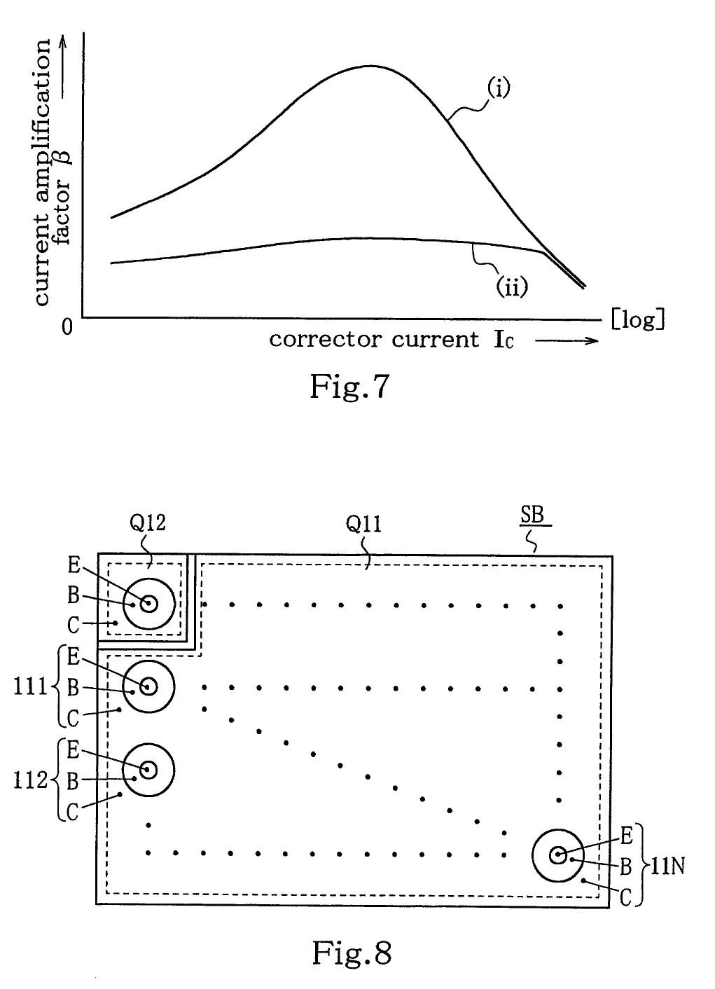

As long as each of the first and second transistor elements Q11 and Q12 is the lateral type transistor, the transistor TD cannot fully eliminate an adverse effect of the variation of the current amplification factor which is peculiar to the lateral type transistor. However, in the transistor TD having the structure as shown in FIG. 5, a current mirror circuit is constructed by the first and second transistor elements Q11 and Q12. For this, a collector current of the first transistor element Q11 will theoretically have a value equal to that mollifying a base current of the transistor TD by a predetermined constant. The base current of the transistor TD and a collector current of the second transistor element Q12 have approximate values, respectively. Thus, the variation of the current amplification factor to the collector current, which is obtained by the entire transistor TD, can be reduced. In this connection, a characteristic of the current amplification factor to the collector, which is obtained by the entire transistor TD, will be shown in FIG. 7 described in detail later.

The transistor TD to be incorporated in the series regulator is required to be a power transistor capable of handling heavy current. Thus, as shown in FIG. 6, the first transistor element Q11 for composing the transistor TD is constructed by N pieces of transistor elements 111 to 11N connected in parallel with each other. For the convenience in designing, all of the transistor elements 111 to 11N composing the first transistor element Q11 is formed in the same dimension and shape as those of the second transistor element Q12.

For the purpose of comparison, given that the control transistor Q1 of FIG. 1 has the same construction as that of the first transistor element Q11 of FIG. 6 and the control transistor Q1 exhibits the same characteristics as that of the first transistor element Q11. That is, assuming that the structural difference between the control transistor Q1 and the transistor TD of the present invention is only the presence the second transistor element Q12. Whereat, each current amplification factor in the conventional control transistor Q1 and the transistor TD of the present invention will be varied as shown in FIG. 7, where the curve (i) indicates a general characteristic variation of the current amplification factor β_{Q1} of the control transistor Q1, and the curve (ii) indicates a general characteristic variation of the current amplification factor β_{TD} of the entire transistor TD.

In FIG. 7, the current amplification factor β_{TD} of the transistor TD in the curve (ii) gently increases in proportion to the increase of the collector current in the low domain of the collector current. The current amplification factor β_{TD} has a peak and is kept in approximately constant value to the wide range of the variation of the collector current around the peak. The peak value of the current amplification factor becomes almost equal to the integer N indicative of the number of the transistor elements composing the first transistor element Q11. After passing through the peak, the current amplification factor β_{TD} gradually decreases in proportion to the increase of the collector current. However, when getting close to the characteristic curve (i) of the current amplification factor β_{Q1} of the control transistor Q1, the current amplification factor β_{TD} is changed in its decrease amount, and then decreases approximately along the characteristic curve (i).

As seen from the curve (ii) in FIG. 7, the value of the current amplification factor β_{TD} of the entire transistor TD is smaller than the current amplification factor β_{Q1} of the control transistor Q1. The value of the current amplification factor β_{TD} can be increased by increasing the number N of the transistor elements 111 to 11N composing the first transistor element Q11. However, it is not allowed to increase the number N excessively. That is, first, as the N is increased, the characteristic curve of the current amplification factor β_{TD} of the transistor TD approaches the characteristic curve of the current amplification factor β_{Q1} of the control transistor Q1 to increase its variation amount. Secondly, the number N is restricted by a limitation due to the area of the semiconductor substrate. These are primary reasons.

In the series regulator employing the transistor TD of the present invention as shown in FIG. 5, increasing a feedback gain of the circuitry composed of an error amplifier 3 and a drive transistor Q2 is provided as a measure for the lowering in the value of the current amplification factor β_{TD}. Even if the feedback gain of the circuitry of the error amplifier 3 and the drive transistor Q2 is increased, the variation amount of the current amplification factor β_{TD} of the transistor TD is small. Thus, any unstable operation of the regulator will not be practically caused.

When manufacturing the transistor TD having the construction shown in FIG. 6, each pattern of the transistor elements (Q12, 111 to 11N) on the semiconductor substrate are, as one example, formed in shapes and at positions as shown in FIG. 8.

In FIG. 8, the transistor TD includes a pattern of the second transistor element Q12 formed at the upper left corner of the semiconductor substrate SB and a pattern of the transistor elements 111 to 11N formed at another positions on the semiconductor substrate SB. As seen in FIG. 6, the collector of the second transistor element Q12 and the collectors of the transistor elements 111 to 11N have the different terminals of the transistor TD to be connected thereto, respectively. Thus, in FIG. 8, the pattern for the region composing the collector (C) of the second transistor element Q12 is formed separately from the pattern for the region composing the collectors (C) of the second transistor elements 111 to 11N.

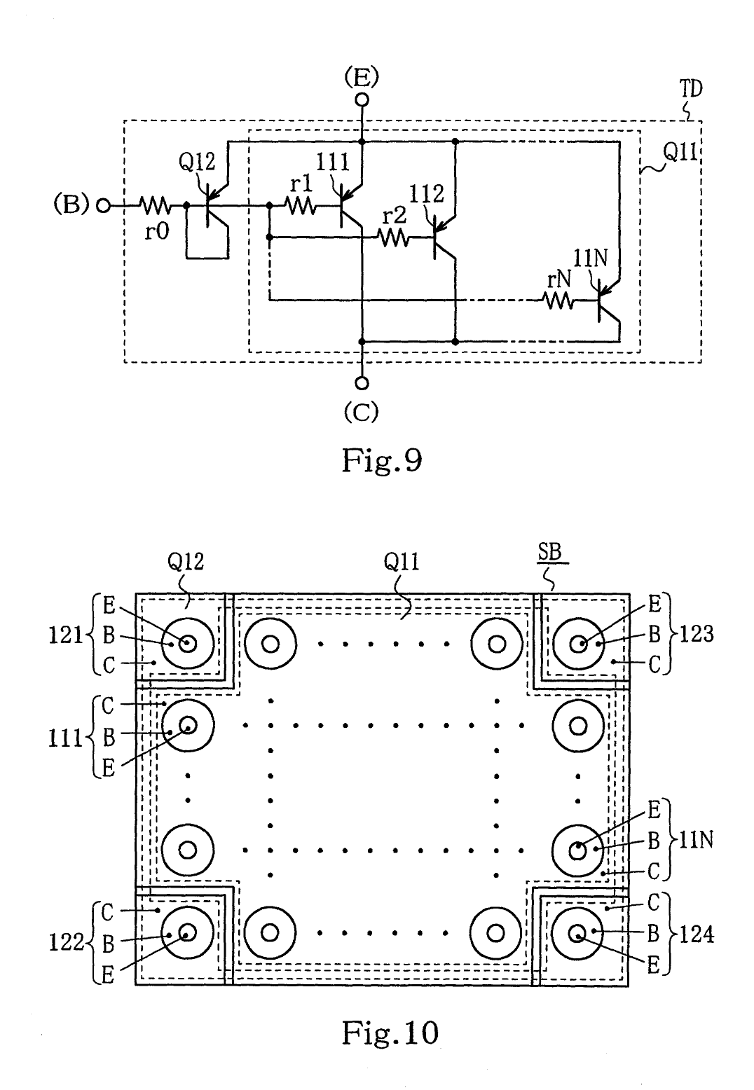

A typical lateral type transistor includes a base region having a low impurity density. Thus, a current path formed in the base region has a high electrical resistance, and the value of the resistance cannot be ignored. In view of this electrical resistance, the transistor TD having the pattern shown in FIG. 8 will practically have a circuitry as shown in FIG. 9.

Specifically, the emitter of the second transistor element Q12 and the emitters of the transistor elements 111 to 11N are connected commonly with each other, and the common connecting point is connected to the emitter terminal (E) of the transistor TD. The collectors of the transistor elements 111-11N are commonly connected with each other, and the common connecting point is connected to the collector terminal (C) of the transistor TD.

The collector of the second transistor element Q12 is short-circuited to the base thereof, and the base is connected to the base terminal (B) of the transistor TD through a resistance r0. The base of the transistor element 111 is connected to the base of the second transistor element Q12 through a resistance r1. Further, the base of the transistor element 11M is connected to the base of the second transistor element Q12 through a resistance rM (where M is an integer in the range of 2 to N). For example, the base of the transistor element 112 may be connected to the base of the second transistor element Q12 through a resistance r2.

In FIG. 8, the transistor element 11N is formed at a furthermost position from the second transistor element Q12. Referring to the circuit diagram of FIG. 9, a resistance rN is interposed between the base of the second transistor element Q12 and the base of the transistor element 11N. The value of the resistance rN naturally increases as the distance between the two associate bases gets longer. When the value of the resistance rN increases, a difference is caused in between respective base-emitter voltages or base currents of the second transistor element Q12 and the transistor element 11N, which are essentially almost identical values in the current mirror circuit. As a result, the action of the transistor element 11N as the transistor for the current mirror circuit is degraded due to the above difference, resulting in deteriorated correlation between the collector current of the transistor element 11N and the collector current of the second transistor element Q12.

Compared with the transistor elements disposed at a position close to the second transistor element Q12, such as the transistor element 111, not only the transistor element 11N but also any other transistor elements disposed away from the second transistor element Q12 are degraded in the action as the transistor for the current mirror circuit. The collector current of each transistor element disposed away from the second transistor element Q12 will be subject to the variation of the current amplification factor β of the transistor element itself. Thus, in the structure having the pattern of FIG. 8, it is presumed that the variation of the current amplification factor β_{TD} of the entire transistor TD to the collector current will increase due to the transistor elements disposed away from the second transistor element Q12.

As show in FIG. 10, in order to cope with this problem, the second transistor element Q12 is constructed by a plurality, for example, four of transistor elements 121 to 124. Further, the transistor elements 111 to 11N composing the first transistor element Q11 and the transistor elements 121 to 124 composing the second transistor element Q12 are dispersedly disposed to provide a uniform distribution density in the given region on the semiconductor substrate SB possibly. More specifically, in consideration of the convenience for the connection of each terminal of the transistor elements, transistor elements 121 to 124 are disposed dispersedly at four corners in the given region of the semiconductor substrate SB. This construction makes it possible to prevent from providing transistor elements inferior particularly in the action as the transistor for the current mirror circuit, such as transistor element 11N as shown in FIG. 8.

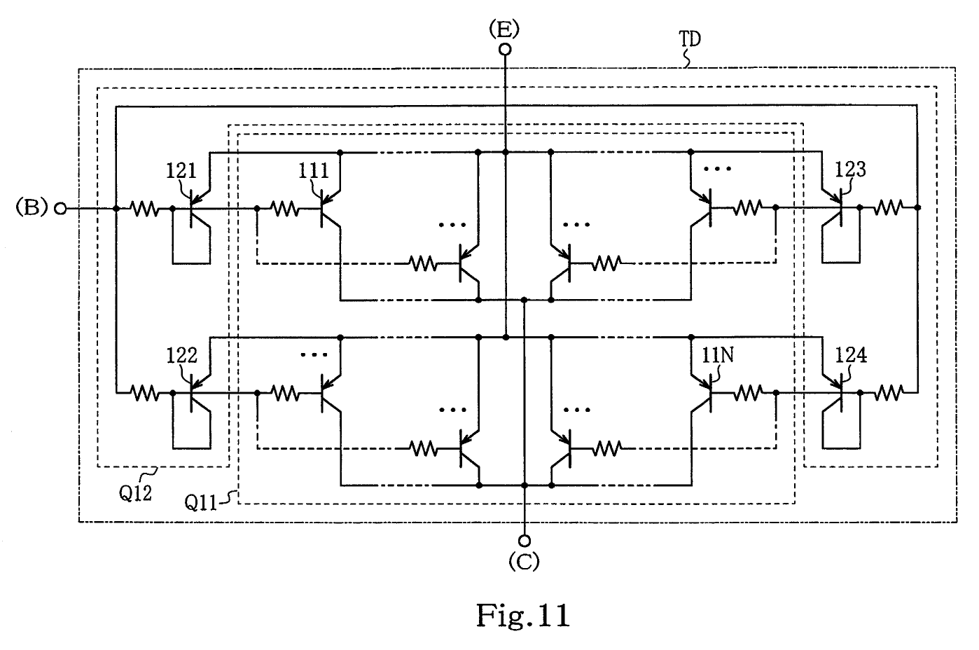

The transistor TD formed in the pattern as shown in FIG. 10 may be represented by an equivalent circuit having a construction as shown in FIG. 11. Specifically, the transistor elements 121 to 124 composing the second transistor element Q12 are dispersedly disposed. The collectors of the transistor elements 121 to 124 are connected commonly to the bases thereof. Each base of the transistor elements 121 to 124 is connected to the base terminal of the transistor TD through an associated resistance.

The base of the transistor element 121 is connected to the bases of about N/4 of the transistor elements including the nearest transistor element 111 among the transistor elements 111 to 11N composing the first transistor elements Q11 through each associated resistance. In the same manner, each of the bases of the transistor elements 122 to 124 composing the second transistor element Q12 is connected to corresponding each ¼ of the bases of remaining about 3N/4 of the transistor elements among the transistor elements 111 to 11N through each associated resistance. The emitters of transistor elements 121 to 124 and the emitters of transistor elements 111 to 11N are connected to the emitter terminal (E) of the transistor TD. The collectors of the transistor elements 111 to 11N are connected to the collector terminal (C) of the transistor TD.

When increasing the number of the transistor elements composing the second transistor element Q12, the ratio of the total collector current of the first transistor elements Q11 to the total collector current of the second transistor element Q12 is reduced, and consequently the current amplification factor β_{TD} of the transistor TD is lowered. Thus, if a high current amplification factor β_{TD} is required, the number of the transistor elements composing the first transistor element Q11 may be appropriately increased, for example, to 4N.

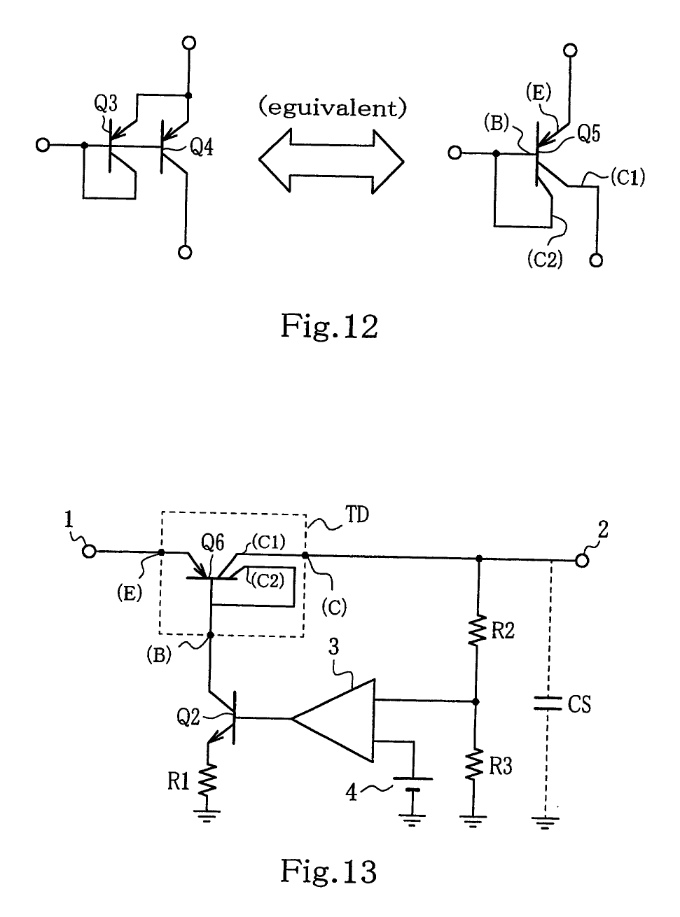

In a bipolar integrated circuit, the lateral type transistor is often used in composing a current source circuit. In this case, the lateral type transistor may be provided in the form of a multi-collector type. For example, as shown in FIG. 12, a current mirror circuit composed of two transistors Q3 and Q4 may be equivalently composed of a multi-collector type transistor Q5 having a first collector (C1) and a second collector (C2) which is connected to a base (B) thereof. A circuit of FIG. 13 is provided by substituting a multi-collector type transistor MCT for the transistor TD shown in FIG. 5.

The transistor MCT of FIG. 13 includes a multi-collector type transistor element Q6 having a second collector (C2) short-circuited to the base thereof, a base terminal (B) provided in a line connected to the second collector (C2) and to the base of the transistor element Q6, an emitter terminal (E) provided in a line connected to the emitter of the transistor element Q6, and a collector terminal (C) provided in a line connected to a first collector (C1) of the transistor element Q6. While the applied transistor is different in type, the equivalent circuit of the transistor MCT of FIG. 13 is structurally the same as that of the transistor TD of FIG. 5. Thus, the transistor MCT has the same operation and effect as those of the transistor TD.

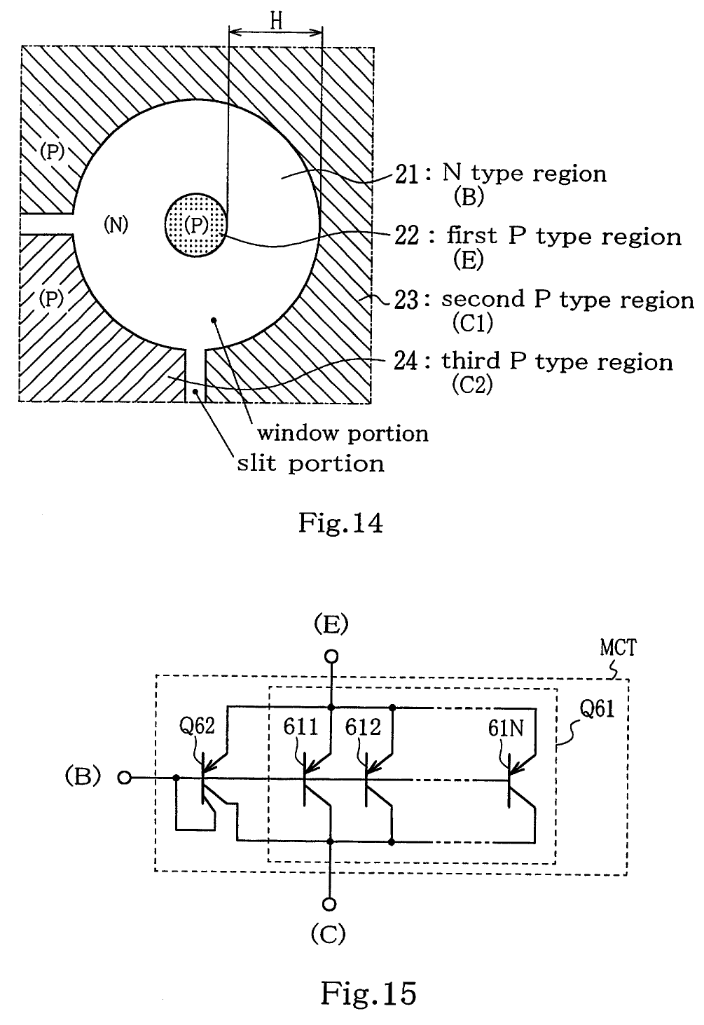

The multi-collector type transistor element can be provided by forming a pattern as schematically shown in FIG. 14 on a semiconductor substrate. The multi-collector type transistor element of FIG. 14 includes an N-type region 21, and first, second and third P-type regions 22, 23 and 24 which are formed mutually separately on the N-type region. The first P-type region 22 is formed in a circular shape. The second and third P-type regions 23 and 24 are formed to cover over the upper surface of the N-region 21 excepting a circular window portion about the first P-region 22 and slit portions. The second and third P-type regions 23 and 24 divided by the slit portions have shapes each surrounding about ¾ and the rest ¼ of the outer periphery of the first P-type region 22, respectively.

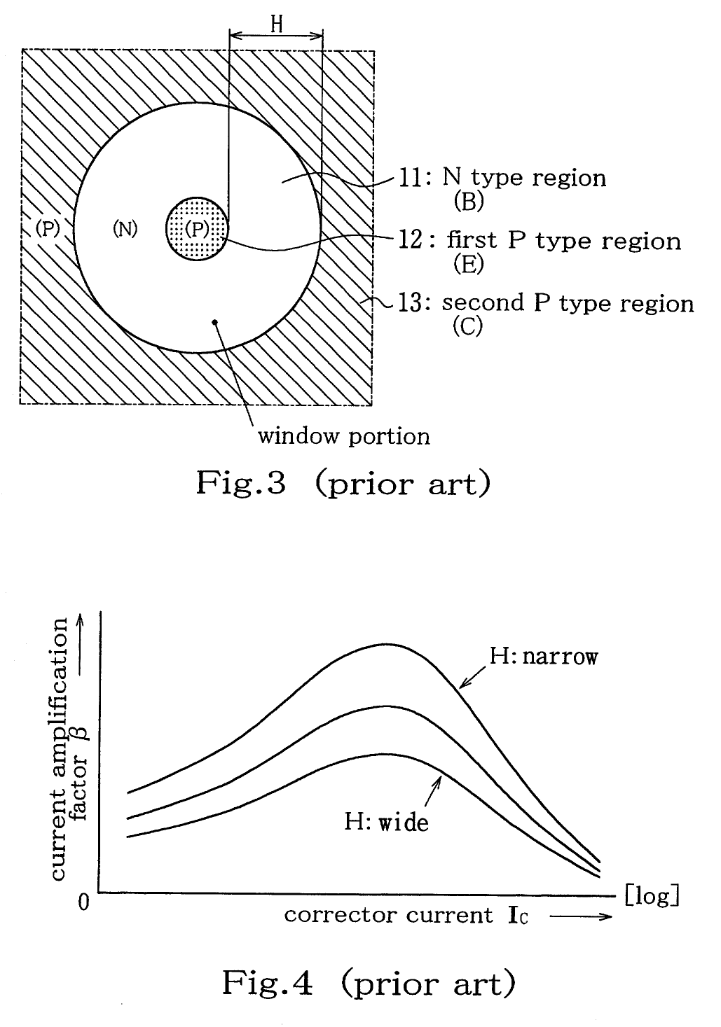

It follows that the pattern shown in FIG. 14 substantially corresponds to that formed by cutting off a part of lower and left portions of the region 13 of FIG. 3 to provide about ¾ part of the resulting region 13 as the second P-type region 23 and provide remaining about ¼ part as the third P-type region 24. The N-type region 21, the first P-type region 22, the second P-type region 23 and the third P-type region 24 serve as a base region, an emitter region, a first collector region and a second collector region, respectively. By providing electrodes on the semiconductor substrate to join with the N-region 21 and the third P-region 24 and then electrically connecting the electrodes by any suitable manner method, the multi-collector type transistor as shown at the right hand side of FIG. 12 can be made.

The transistor MCT in FIG. 13 is required to be formed as a power transistor having an ability of supplying adequate collector current and providing a sufficiently high current amplification factor. It is generally difficult to obtain the ability of supplying a large collector current and the high current amplification factor only by means of one transistor element having the pattern as shown in FIG. 14. Thus, the multi-collector type transistor element having the pattern shown in FIG. 14 and a plurality of conventional transistor elements each having the pattern shown in FIG. 3 are provided on a semiconductor substrate. Then, by connecting these transistor elements each other in a manner as shown in FIG. 15, a transistor MCT having the ability of supplying adequate collector current and providing a sufficiently high current amplification factor can be obtained. The transistor MCT shown in FIG. 15 has the following structure.

A base and a second collector of a multi-collector type transistor element Q62 are connected with each other. An emitter of the multi-collector type transistor element Q62 and emitters of a plurality of conventional transistor elements 611 to 61U are connected commonly with each other, and the common connecting point is connected to the emitter terminal (E) of the transistor MCT. A first collector of the transistor element Q62 and collectors of the plurality of transistor elements 611 to 61U are connected commonly with each other, and the common connecting point is connected to the collector terminal (C) of the transistor MCT. The base of the transistor element Q62 and bases of the plurality of transistor elements 611 to 61U are connected commonly with each other, and the common connecting point is connected to the base terminal (B) of the transistor MCT. The transistor element Q62 serves as the second transistor element, and the transistor elements 611 to 61U connected in parallel with each other serve as the first transistor element Q61.

In the transistor MCT having such a construction, the total area of the P-type regions forming the first collector of the second transistor element Q62 and the collectors of transistor elements 611 to 61U is represented by S1 and the area of the P-type region forming the second collector of the second transistor element Q62 is represented by S2, where the term of “area” means the area of the surface of the P-region forming the collector, which is opposed to the P-type region forming the emitter. Thus, by substituting the collector area ratio S1/S2 for the N, the transistor MCT having the construction as shown in FIG. 15 can be regarded as with the transistor TD described above. Accordingly, as with the current amplification factor β_{TD} of the transistor TD, the current amplification factor β_{MCT} of the transistor MCT exhibits substantially the same characteristic as the curve (ii) of FIG. 7.

Again, the typical lateral type transistor includes a base region having a low impurity density. Thus, a current path formed in the base region has a high electrical resistance, and it can be anticipated that the transistor element 61U disposed at furthermost position from the second transistor element Q62 is significantly degraded in the action as the transistor for the current mirror circuit.

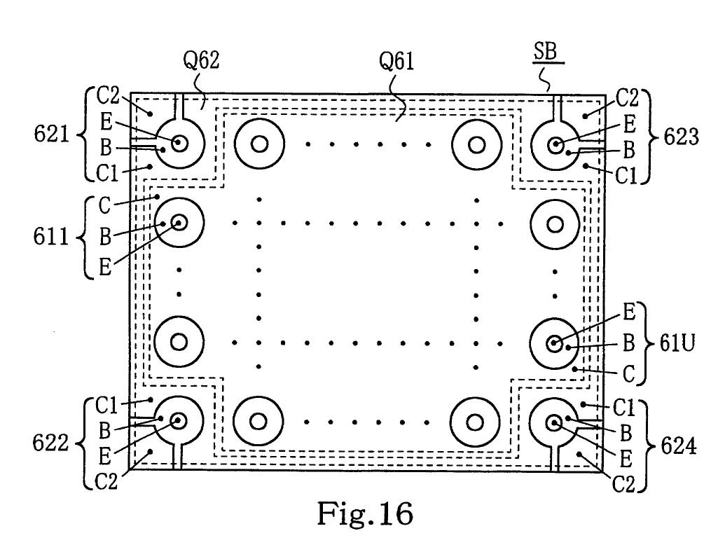

In view of the above problem, as is shown in FIG. 16, the second transistor element Q62 is composed of a plurality, for instance, four of transistor elements 621 to 624. Then, the transistor elements 611 to 61N composing the first transistor element Q62 and the transistor elements 621 to 624 composing the second transistor element Q12 are dispersedly disposed to provide a uniform distribution density on the semiconductor substrate SB possibly. More specifically, the transistor elements 621 to 624 are disposed dispersedly at the four corners of the given region of the semiconductor substrate SB, and the transistor elements 611 to 61U are disposed at another positions on the semiconductor substrate SB. This construction makes it possible to prevent from providing transistor elements inferior in the action as the transistor for the current mirror circuit, as described in conjunction with FIGS. 10 and 11.

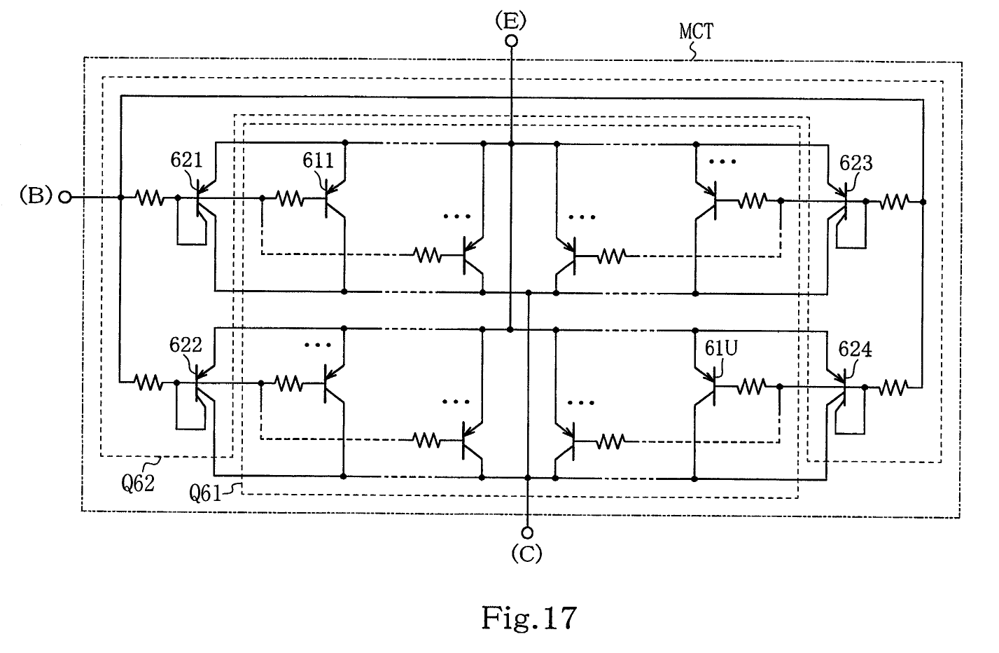

The transistor MCT formed in the pattern as shown in FIG. 16 may be represented by an equivalent circuit having a construction as shown in FIG. 17.

Specifically, the multi-collector type transistor elements 621 to 624 composing the second transistor element Q62 are dispersedly disposed. The second collectors of the transistor elements 621 to 624 are connected the bases thereof, respectively. Each base of the transistor elements 621 to 624 is connected to the base terminal (B) of the transistor MCT through an associated resistance.

The base of the multi-collector type transistor element 621 is connected to the bases of about U/4 of the transistor elements including the nearest transistor element 611 among the conventional transistor elements 611 to 61U composing the first transistor elements Q61 through each associated resistance. In the same manner, each of the bases of the multi-collector type transistor elements 622 to 624 is connected to corresponding each U/4 of the bases of the transistor elements composing the transistor element Q61 through each associated resistance. The emitters of transistor elements 621 to 624 and the emitters of transistor elements 611 to 61U are connected to the emitter terminal (E) of the transistor MCT. The first collectors of the transistor elements 621 to 624 and the collectors of the transistor elements 611 to 61N are connected to the collector terminal (C) of the transistor MCT.

When increasing the number of the transistor elements composing the second transistor element Q62, the collector area ratio (S1/S2) is reduced, and consequently the current amplification factor β_{MCT} of the transistor MCT is lowered. Thus, if a high current amplification factor β_{MCT} is required, the number of the transistor elements composing the first transistor element Q62 may be appropriately increased.

While the transistor elements 611 to 61U composing the first transistor elements Q61 are conventional transistor elements in the embodiment as shown in FIGS. 15 to 17, multi-collector type transistor elements having collectors connected commonly with each other may be used as the transistor elements 611 to 61U.

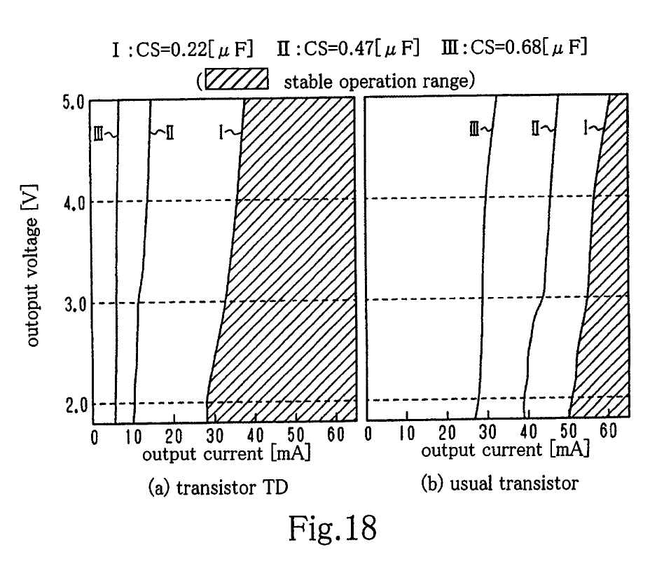

For reference, a measurement result of characteristics of a regulator is shown in FIG. 18. The regulator has been produced by actually fabricating a transistor TD having the pattern of FIG. 8 and the circuitry of FIG. 9, and then incorporating the fabricated transistor TD into the series regulator as shown in FIG. 5. The left graph (a) of FIG. 18 shows the characteristics of the series regulator incorporated with the transistor TD according to the present invention, and the right graph (b) shows the characteristics of a series regulator as a comparative example incorporated with a conventional power transistor. The three characteristic curves (I, II and III) in each graph show a relationship between an output voltage and output current allowing each of the current regulators to continuously maintain a stable operation when three phase-correcting capacitors CS each having a given different capacitance are connected to the regulators. The right side of each characteristic curve corresponds to the region of the output conditions for providing the stable operation of the regulators, and the left side of each characteristic curve corresponds to the region of the output conditions for providing the unstable operation of the regulators.

In the transistor TD of the present invention which was used in the measurement of the regulator characteristics, the number of transistor elements composing the first transistor elements Q11 was 142, and the number of transistor elements composing the second transistor elements Q12 was 1 (one). On the other hand, the conventional power transistor was constructed by 143 of transistor elements connected in parallel with each other as with the first transistor elements Q11. Naturally, the transistor elements composing the transistor TD and the transistor elements composing the conventional power transistor were equalized in the pattern forms and the forming conditions. Ceramic capacitors (CSR [symbol] 0.001 Ω) were used as the phase correcting capacitors CS connected between the output terminal 2 and the ground in the test to stabilize the operation.

Comparing respective curves I of the characteristic diagrams (a) and (b) in case of the phase correcting capacitor CS having a capacitance of 0.22 μF, it is apparent that the current regulator using the transistor TD of the present invention can provide the stable operation even in the range of low output current. In other words, using the transistor TD of the present invention in the series regulator to obtain a given output current may allow the phase-correcting capacitor to reduce its capacitance to stabilize the operation of the regulator. Furthermore, a pattern of FIG. 10 and a circuitry of FIG. 11 may be used in the transistor TD, and the multi-collector type transistor MCT may be used as a substitute for the transistor TD. In these cases, similar results could also be obtained.

What is claimed is:

1. A semiconductor device comprising:
a given region formed on a semiconductor substrate;
a first transistor element formed in said given region;
a plurality of second transistor elements formed dispersedly in said given region and composing a current mirror circuit in combination with said first transistor element;
a first terminal provided in a line connected to a collector of said first transistor element;
a second terminal provided in a line connected commonly to each emitter of said first and second transistor elements; and
a third terminal provided in a line connected commonly to each base of said first and second transistor elements.

2. A semiconductor device as defined in claim 1, wherein said first and second transistor elements are a lateral type PNP transistor.

3. A semiconductor device as defined in claim 2, wherein said given region is an N-type semiconductor region forming the common base of said first and second transistor elements.

4. A semiconductor device as defined in claim 1, wherein said semiconductor device is used as a control transistor of a series regulator.

5. A semiconductor device comprising:
a given region formed on a semiconductor substrate;
at least one first transistor element formed in said given region;
at least one multi-collector type second transistor element formed in said given region and provided with a first collector and a second collector, said second collector being electrically connected to a base of said second transistor element;
a first terminal provided in a line connected commonly to a collector of said first transistor element and the first collector of said second transistor element;
a second terminal provided in a line connected commonly to each emitter of said first and second transistor elements; and
a third terminal provided in a line connected to each base of said first and second transistor elements.

6. A semiconductor device as defined in claim 5, wherein the plural number of said second transistor elements are provided dispersedly in said given region.

7. A semiconductor device as defined in claim 5, wherein said first and second transistor elements are a lateral type PNP transistor.

8. A semiconductor device as defined in claim 5, wherein said given region is an N-type semiconductor region forming the common base of said first and second transistor elements.

9. A semiconductor device as defined in claim 5, wherein said semiconductor device is used as a control transistor of a series regulator.

10. A semiconductor device comprising:
an N-type semiconductor region formed on a semiconductor substrate;
a plurality of lateral multi-collector type PNP transistor elements formed dispersedly in said N-type semiconductor region and each of which has a first collector and a second collector, said second collector being electrically connected to a corresponding base of each of said PNP transistor elements;
a first terminal provided in a line connected to each first collector of said transistor elements;
a second terminal provided in a line connected to each emitter of said transistor elements; and
a third terminal provided in a line connected to each base of said transistor elements.

11. A semiconductor device in which a transistor for control is formed in its inside, for controlling the quantity of current flow, said transistor for control comprising:
a first transistor element formed in a given region;
a second transistor element formed in said given region and composing a current mirror circuit in combination with said first transistor element;
a first terminal provided in a line connected to a collector of said first transistor element;
a second terminal provided in a line connected commonly to each emitter of said first and second transistor elements; and
a third terminal provided in a line connected commonly to each base of said first and second transistor elements.

12. A semiconductor device as defined in claim 11, wherein said first and second transistor elements are a lateral type PNP transistor.

13. A semiconductor device as defined in claim 12, wherein said given region is an N-type semiconductor region forming the common base of said first and second transistor elements.
